(19) United States
(12) Patent Application Publication
(10) Pub. No.: US 2025/0293654 A1
(43) Pub. Date: Sep. 18, 2025

(54) COMMON MODE FILTER

(71) Applicant: TDK Corporation, Tokyo (JP)

(72) Inventors: Takeshi OKUMURA, Tokyo (JP); Kouji KAWAMURA, Tokyo (JP); Hidenori TSUTSUI, Tokyo (JP); Hibiki MIYASAKA, Tokyo (JP); Yosuke MIZUTANI, Tokyo (JP); Yoshinori KINOSHITA, Tokyo (JP)

(21) Appl. No.: 19/042,197

(22) Filed: Jan. 31, 2025

(30) Foreign Application Priority Data
Mar. 18, 2024 (JP) 2024-042501

(51) Int. Cl. H03H 1/00; H01F 27/28; H01F 27/29; H01F 27/32

(52) U.S. Cl. CPC H03H 1/0007; H01F 27/2804; H01F 27/29; H01F 27/323; H01F 2027/2809; H03H 2001/0078; H03H 2001/0092

(57) ABSTRACT

Disclosed herein is a common mode filter that includes: a plurality of conductor layers stacked with an insulating layer interposed therebetween, the plurality of conductor layers including at least first and second conductor layers; and first, second, third, and fourth terminal electrodes. The first conductor layer has a spiral-shaped first coil pattern having an outer peripheral end connected to the first terminal electrode and an inner peripheral end connected to the third terminal electrode. The second conductor layer has a spiral-shaped second coil pattern having an outer peripheral end connected to the second terminal electrode and an inner peripheral end connected to the fourth terminal electrode. The outermost turn of the first coil pattern has a first non-overlap section that is wound at least by ¼ turn without overlapping the outermost turn of the second coil pattern.

### CROSS-REFERENCE TO RELATED APPLICATION

This application claims the benefit of Japanese Patent Application No. 2024-042501, filed on Mar. 18, 2024, the entire disclosure of which is incorporated by reference herein.

### BACKGROUND OF THE ART

### Field of the Art

The present disclosure relates to a common mode filter and, more particularly, to a common mode filter having a plurality of coil patterns stacked one on another through insulating layers.

### Description of Related Art

JP 2017-139368A discloses a chip-type common mode filter having a plurality of coil patterns stacked one on another through insulating layers.

In such a type of common mode filter, inter-wire capacitance between adjacent coil patterns has influence on high-frequency characteristics.

### SUMMARY

The present disclosure describes a technology for improving, in a common mode filter having a plurality of coil patterns stacked one on another through insulating layers, high-frequency characteristics by reducing inter-wire capacitance in a section near a terminal electrode.

A common mode filter according to an aspect of the present disclosure includes: a plurality of conductor layers stacked with an insulating layer interposed therebetween, the plurality of conductor layers including at least first and second conductor layers; and first, second, third, and fourth terminal electrodes. The first conductor layer has a spiral-shaped first coil pattern having an outer peripheral end connected to the first terminal electrode and an inner peripheral end connected to the third terminal electrode. The second conductor layer has a spiral-shaped second coil pattern having an outer peripheral end connected to the second terminal electrode and an inner peripheral end connected to the fourth terminal electrode. The outermost turn of the first coil pattern has a first non-overlap section that is wound at least by ¼ turn without overlapping the outermost turn of the second coil pattern.

A common mode filter according to another aspect of the present disclosure includes: a plurality of conductor layers stacked with an insulating layer interposed therebetween, the plurality of conductor layers including at least first and second conductor layers; and first, second, third, and fourth terminal electrodes. The first conductor layer has a spiral-shaped first coil pattern having an outer peripheral end connected to the first terminal electrode and an inner peripheral end connected to the third terminal electrode. The second conductor layer has a spiral-shaped second coil pattern having an outer peripheral end connected to the second terminal electrode and an inner peripheral end connected to the fourth terminal electrode. The innermost turn of the first coil pattern has a first non-overlap section that is wound at least by ¼ turn without overlapping the innermost turn of the second coil pattern.

### BRIEF DESCRIPTION OF THE DRAWINGS

The above features and advantages of the present disclosure will be more apparent from the following description of some embodiments taken in conjunction with the accompanying drawings, in which:

FIG. 1 is a schematic perspective view illustrating the outer appearance of a common mode filter 1 according to a first embodiment of the technology described herein;

FIG. 2 is a schematic plan view for explaining the pattern shape of the conductor layer 100;

FIG. 3 is a schematic plan view of the insulating layer 10;

FIG. 4 is a schematic plan view for explaining the pattern shape of the conductor layer 200;

FIG. 5 is a schematic plan view of the insulating layer 20;

FIG. 6 is a schematic plan view for explaining the pattern shape of the conductor layer 300;

FIG. 7 is a schematic plan view of the insulating layer 30;

FIG. 8 is an equivalent circuit diagram of the common mode filter 1;

FIG. 9 is a schematic cross-sectional view of the common mode filter 1;

FIG. 10 is a graph for explaining effects obtained by the first embodiment;

FIG. 11 is a schematic plan view for explaining the pattern shape of a conductor layer 100A used for a common mode filter according to a second embodiment of the technology described herein;

FIG. 12 is a schematic cross-sectional view of the common mode filter according to the second embodiment;

FIG. 13 is a schematic plan view for explaining the pattern shape of a conductor layer 100B used for a common mode filter according to a third embodiment of the technology described herein;

FIG. 14 is a schematic plan view for explaining the pattern shape of a conductor layer 100C used for a common mode filter according to a fourth embodiment of the technology described herein;

FIG. 15 is a schematic plan view for explaining the pattern shape of a conductor layer 300A used for the common mode filter according to the fifth embodiment;

FIG. 16 is a schematic plan view of the insulating layer 30 used for the common mode filter according to the fifth embodiment;

FIG. 17 is a schematic plan view for explaining the pattern shape of the conductor layer 400;

FIG. 18 is a schematic plan view of the insulating layer 40; and

FIG. 19 is a schematic cross-sectional view of a common mode filter according to the fifth embodiment.

### DETAILED DESCRIPTION OF THE EMBODIMENTS

Some embodiments of the present disclosure will be explained below in detail with reference to the accompanying drawings.

### First Embodiment

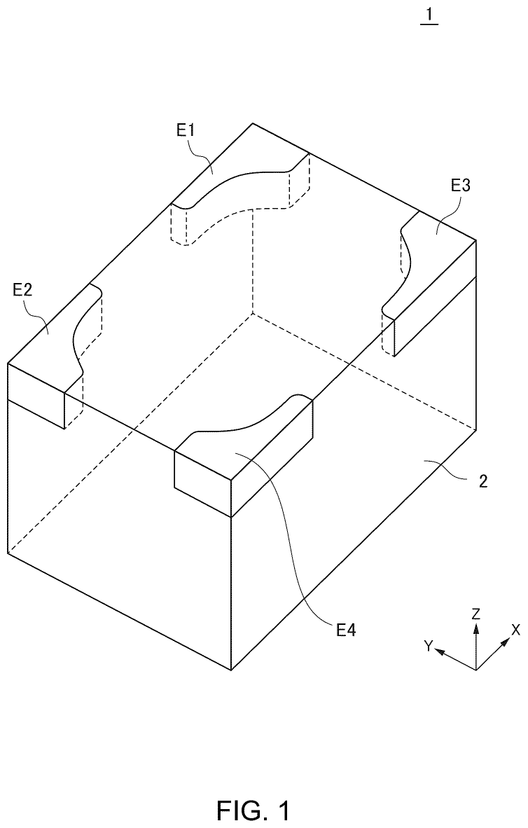

FIG. 1 is a schematic perspective view illustrating the outer appearance of a common mode filter 1 according to a first embodiment of the technology described herein.

The common mode filter 1 according to the first embodiment is a surface-mount type chip component and includes, as illustrated in FIG. 1, an element body 2 and four terminal electrodes E1 to E4 embedded in the element body 2. As described later, the element body 2 embeds therein three conductor layers 100, 200, and 300 which are stacked one on another through insulating layers.

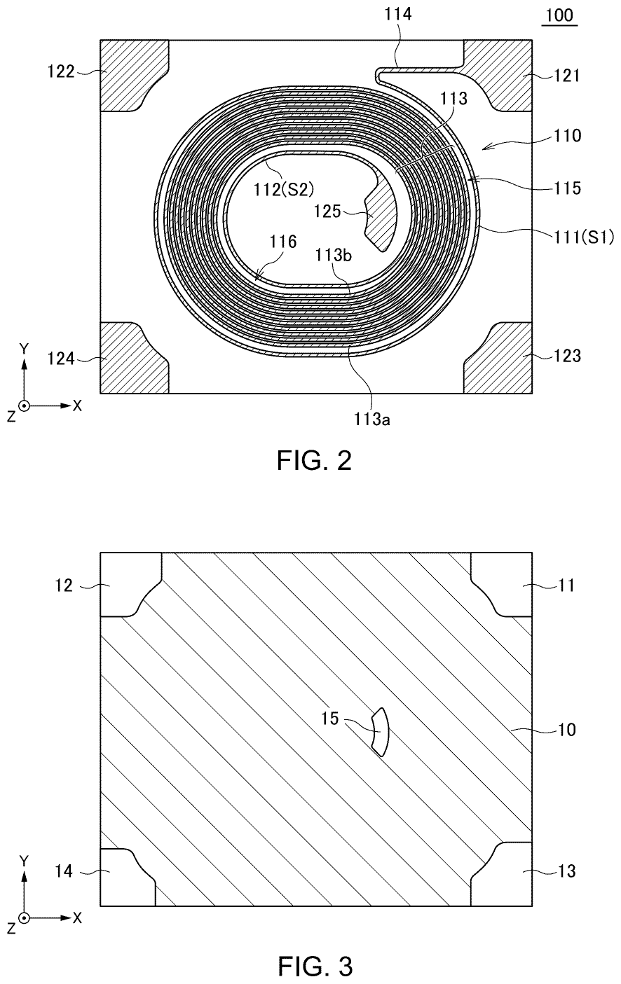

FIG. 2 is a schematic plan view for explaining the pattern shape of the conductor layer 100.

The conductor layer 100 is the lowermost conductor layer and has a spiral coil pattern 110 and connection patterns 121 to 125. In the example illustrated in FIG. 2, the coil pattern 110 has about 12 turns and includes an outermost turn 111, an innermost turn 112, and an intermediate turn 113 positioned between (inclusive) a second turn (turn 113a) counting from the outermost peripheral side and a second turn (turn 113b) counting from the innermost peripheral side. The intermediate turn 113 has about 10 turns. The outer peripheral end of the coil pattern 110 is connected to the connection pattern 121 by way of a lead-out part 114. The inner peripheral end of the coil pattern 110 is connected to the connection pattern 125. The coil pattern 110 is wound right-handed (clockwise) from the outer peripheral end to the inner peripheral end, whereas the lead-out part 114 linearly extends in the negative X-direction from the outer peripheral end to the inner peripheral end without being wound right-handed (clockwise). The connection patterns 122 to 124 are each independently provided without being connected to another conductor pattern in the conductor layer 100.

FIG. 3 is a schematic plan view of the insulating layer 10.

The insulating layer 10 is positioned between the conductor layers 100 and 200 and has openings 11 to 15. The openings 11 to 15 are formed at positions respectively exposing therethrough the connection patterns 121 to 125.

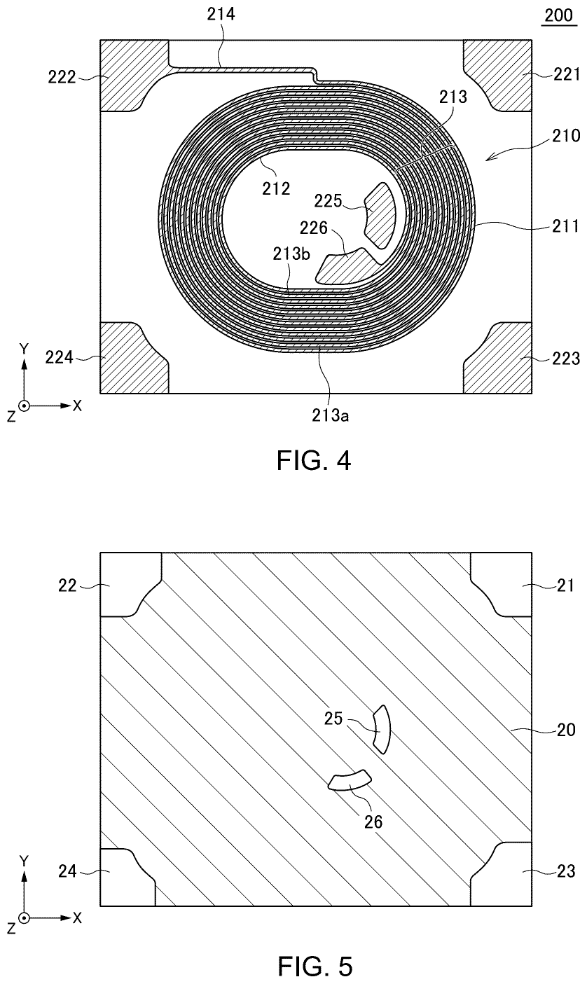

FIG. 4 is a schematic plan view for explaining the pattern shape of the conductor layer 200.

The conductor layer 200 has a spiral coil pattern 210 and connection patterns 221 to 226. In the example illustrated in FIG. 4, the coil pattern 210 has about 12 turns and includes an outermost turn 211, an innermost turn 212, and an intermediate turn 213 positioned between the outermost and innermost turns 211 and 212, starting from a second turn (turn 213a) counting from the outermost peripheral side to a second turn (turn 213b) counting from the innermost peripheral side. The intermediate turn 213 has about 10 turns. That is, the number of turns of the coil pattern 110 and that of the coil pattern 210 are substantially the same. When there is a difference between the numbers of turns of the coil patterns 110 and 210 due to the position of the lead-out part or the like, the difference in the number of turns needs to be ½ or less in order to achieve a function as a common mode filter.

The outer peripheral end of the coil pattern 210 is connected to the connection pattern 222 by way of a lead-out part 214. The inner peripheral end of the coil pattern 210 is connected to the connection pattern 226. The coil pattern 210 is wound right-handed (clockwise) from the outer peripheral end to the inner peripheral end, whereas the lead-out part 214 linearly extends in the positive X-direction from the outer peripheral end to the inner peripheral end. The connection patterns 221, 223, 224, and 225 are each independently provided without being connected to another conductor pattern in the conductor layer 200. The connection patterns 221 to 225 are connected respectively to the connection patterns 121 to 125 through the respective openings 11 to 15 formed in the insulating layer 10.

FIG. 5 is a schematic plan view of the insulating layer 20.

The insulating layer 20 is positioned between the conductor layers 200 and 300 and has openings 21 to 26. The openings 21 to 26 are formed at positions respectively exposing therethrough the connection patterns 221 to 226.

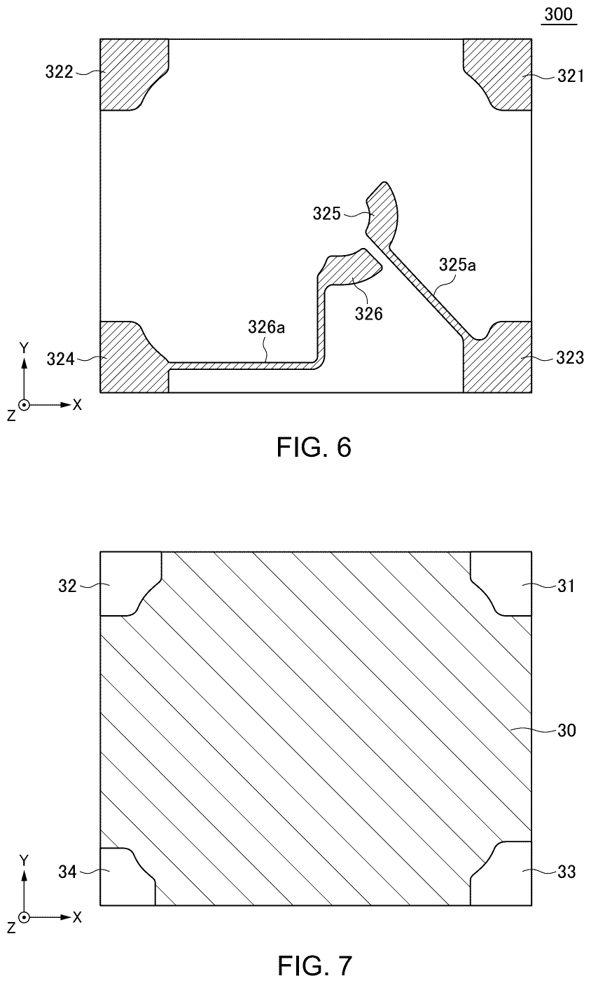

FIG. 6 is a schematic plan view for explaining the pattern shape of the conductor layer 300.

The conductor layer 300 has connection patterns 321 to 326. The connection patterns 321 to 326 are connected respectively to the connection patterns 221 to 226 through the respective openings 21 to 26 formed in the insulating layer 20. The connection pattern 325 is connected to the connection pattern 323 by way of a lead-out part 325a. The connection pattern 326 is connected to the connection pattern 324 by way of a lead-out part 326a.

FIG. 7 is a schematic plan view of the insulating layer 30.

The insulating layer 30 is the uppermost insulating layer and has openings 31 to 34. The openings 31 to 34 are formed at positions respectively exposing therethrough the connection patterns 321 to 324. The terminal electrodes E1 to E4 illustrated in FIG. 1 are connected respectively to the connection patterns 321 to 324 through the respective openings 31 to 34.

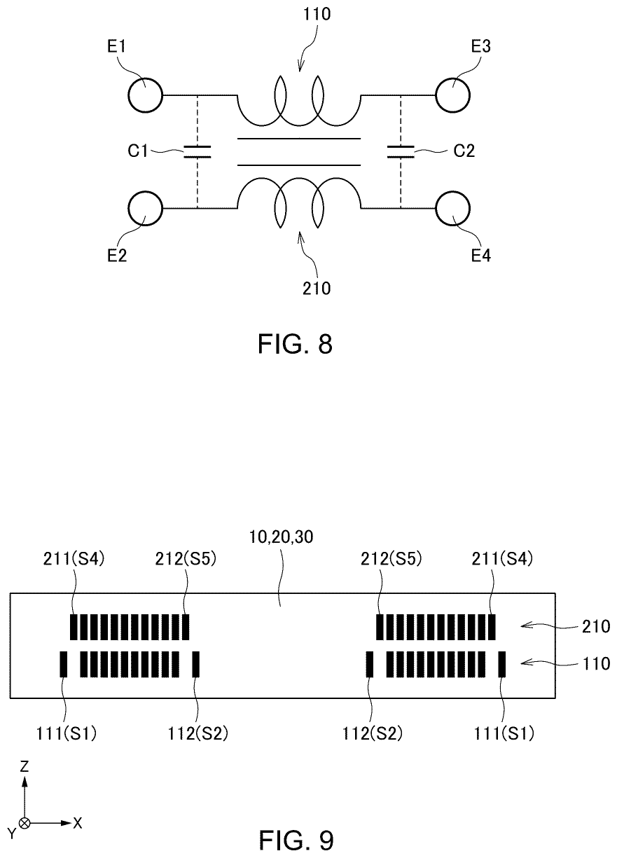

With the above configuration, the outer peripheral end of the coil pattern 110 is connected to the terminal electrode E1, the outer peripheral end of the coil pattern 210 is connected to the terminal electrode E2, the inner peripheral end of the coil pattern 110 is connected to the terminal electrode E3, and the inner peripheral end of the coil pattern 210 is connected to the terminal electrode E4. As a result, as illustrated in FIG. 8, the coil pattern 110 connected between the terminal electrodes E1 and E3 and the coil pattern 210 connected between the terminal electrodes E2 and E4 are coupled to each other.

As illustrated in FIG. 2, in the present embodiment, the radial space between adjacent turns of the coil pattern 110 is not constant, but a space 115 between the outermost turn 111 and the turn 113a and a space 116 between the innermost turn 112 and the turn 113b are made larger than the spaces each between the turns constituting the intermediate turn 113. The spaces 115 and 116 are each larger than the pattern width of the coil pattern 210. The radial space between the turns constituting the intermediate turn 113 is substantially constant. On the other hand, as illustrated in FIG. 4, the radial space between adjacent turns of the coil pattern 210 is substantially constant.

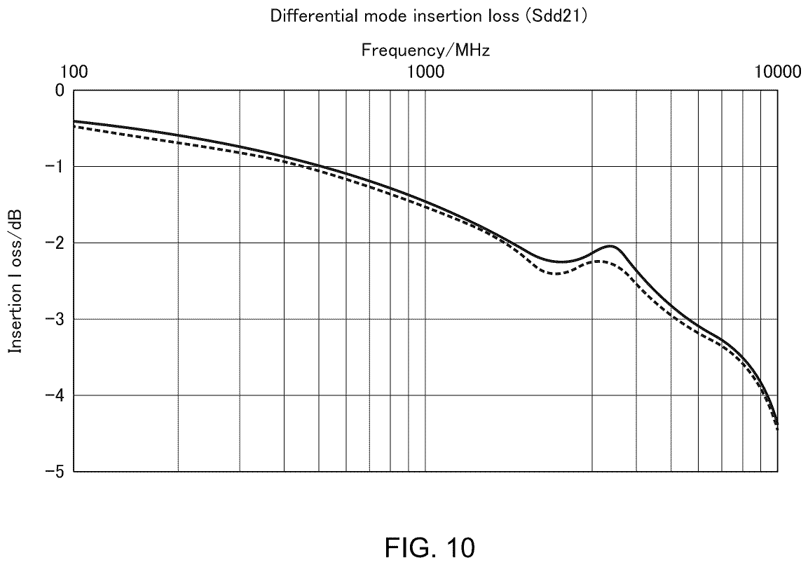

Thus, as illustrated in FIG. 9 which is a schematic cross-sectional view, the outermost turn 111 of the coil pattern 110 and the outermost turn 211 of the coil pattern 210 do not overlap each other at least partially, and the innermost turn 112 of the coil pattern 110 and the innermost turn 212 of the coil pattern 210 do not overlap each other at least partially. A part of the outermost turn 111 of the coil pattern 110 that do not overlap the outermost turn 211 of the coil pattern 210 constitutes a non-overlap section S1. A part of the innermost turn 112 of the coil pattern 110 that do not overlap the innermost turn 212 of the coil pattern 210 constitutes a non-overlap section S2. A part of the outermost turn 211 of the coil pattern 210 that do not overlap the outermost turn 111 of the coil pattern 110 constitutes a non-overlap section S4. A part of the innermost turn 212 of the coil pattern 210 that do not overlap the innermost turn 112 of the coil pattern 110 constitutes a non-overlap section S5.

As described above, since the outermost turns 111 and 211 of the coil patterns 110 and 210 respectively have the non-overlap sections S1 and S4, inter-wire capacitance occurring between the outermost turns 111 and 211 is reduced, with the result that a capacitance component C1 around the terminal electrodes E1 and E2 is reduced. Similarly, since the innermost turns 112 and 212 of the coil patterns 110 and 210 respectively have the non-overlap sections S2 and S5, inter-wire capacitance occurring between the innermost turns 112 and 212 is reduced, with the result that a capacitance component C2 around the terminal electrodes E3 and E4 is reduced.

The turns constituting the intermediate turn 113 of the coil pattern 110 overlap their corresponding turns constituting the intermediate turn 213 of the coil pattern 210. This enhances coupling between the coil patterns 110 and 210.

The non-overlap section S1 of the coil pattern 110 may be constituted by the entire outermost turn 111 or by a part of the outermost turn 111; however, to achieve an effect of reducing the capacitance component C1, at least ¼ of the outermost turn 111 needs to be the non-overlap section S1, and ½ or more of the outermost turn 111 may be the non-overlap section S1. In other words, the non-overlap section S1 of the coil pattern 110 refers not to a section like the lead-out part 114 but to a section wound in the same direction along the turn 113a and including at least a part extending in the X-direction and a part extending in the Y-direction.

Similarly, the non-overlap section S2 of the coil pattern 110 may be constituted by the entire innermost turn 112 or by a part of the innermost turn 112; however, to achieve an effect of reducing the capacitance component C2, at least ¼ of the innermost turn 112 needs to be the non-overlap section S2, and ½ or more of the innermost turn 112 may be the non-overlap section S2. In other words, the non-overlap section S2 of the coil pattern 110 refers to a section wound in the same direction along the turn 113b and including at least a part extending in the X-direction and a part extending in the Y-direction.

The non-overlap sections S1 and S2 may be adjusted in length based on the capacitance components C1 and C2 required. However, when the lengths of the non-overlap sections S1 and S2 exceed one turn, coupling between the coil patterns 110 and 120 is reduced, and thus the lengths of the non-overlap sections S1 and S2 may be one turn or less.

FIG. 10 is a graph for explaining effects obtained by the first embodiment. The graph illustrates a simulation result indicating the insertion loss of a differential mode signal (Sdd21). In the graph of FIG. 10, the solid curve represents the characteristics of the common mode filter 1 according to the present embodiment, and the dashed curve represents the characteristics of a common mode filter according to a comparative example not having the non-overlap section, apart from the lead-out parts 114 and 214, a portion therearound, and a portion around the inner peripheral end. That is, in the coil pattern 110 of the common mode filter according to the comparative example, the radial space between adjacent turns is substantially constant.

As can be seen from the graph of FIG. 10, the common mode filter 1 according to the present embodiment has a reduced insertion loss of a differential mode signal compared with the common mode filter according to the comparative example. The reason for this is considered to be the reduction effect of the capacitance components C1 and C2 around the terminal electrodes E1 to E4 due to the presence of the non-overlap section.

To further reduce the capacitance components C1 and C2, the pattern widths of the non-overlap sections S1, S2, S4, and S5 may be made smaller than the pattern widths of the turns constituting the intermediate turns 113 and 213.

### Second Embodiment

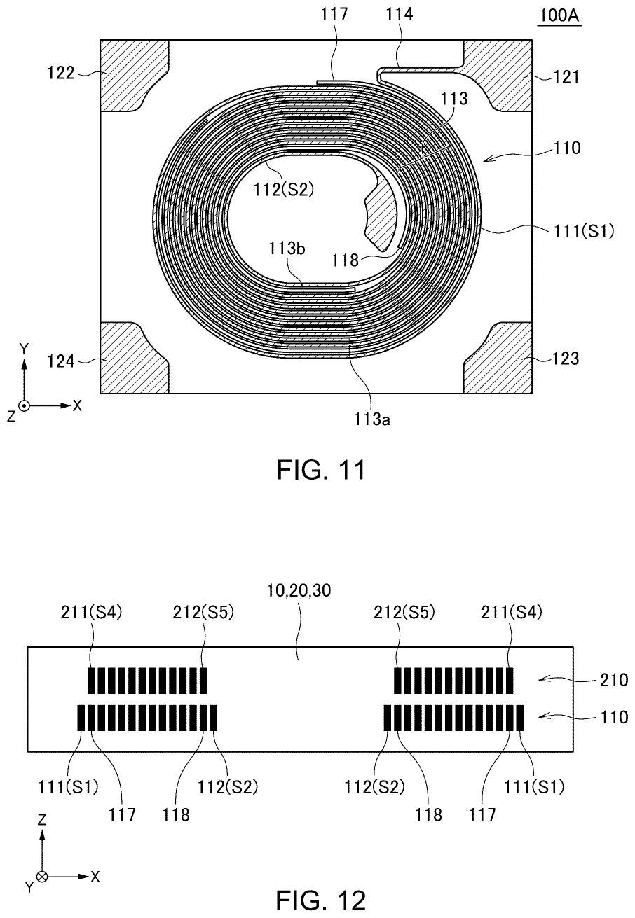

FIG. 11 is a schematic plan view for explaining the pattern shape of a conductor layer 100A used for a common mode filter according to a second embodiment of the technology described herein. FIG. 12 is a schematic cross-sectional view of the common mode filter according to the second embodiment.

As illustrated in FIGS. 11 and 12, the conductor layer 100A used for the common mode filter according to the second embodiment differs from the above-described conductor layer 100 in that it additionally has dummy patterns 117 and 118. Other basic configurations are the same as those of the common mode filter 1 according to the first embodiment, so the same reference numerals are given to the same elements, and overlapping description will be omitted.

The dummy pattern 117 is a pattern disposed between the non-overlap section S1 of the outermost turn 111 and the turn 113a and is in a floating state (not connected to the coil pattern 110). The dummy pattern 117 overlaps the non-overlap section S4 of the outermost turn 211 of the coil pattern 210.

The dummy pattern 118 is a pattern disposed between the non-overlap section S2 of the innermost turn 112 and the turn 113b and is in a floating state (not connected to the coil pattern 110). The dummy pattern 118 overlaps the non-overlap section S5 of the innermost turn 212 of the coil pattern 210.

The dummy patterns 117 and 118 function as bases for respectively forming the outermost and innermost turns 211 and 212 of the coil pattern 210. The presence of the thus-configured dummy patterns 117 and 118 can alleviate process difficulty in formation of the coil pattern 210. To provide the dummy patterns 117 and 118, the pattern pitch between the non-overlap section S1 of the outermost turn 111 and the turn 113a and the pattern pitch between the non-overlap section S2 of the innermost turn 112 and the turn 113b are set to twice or more of the pattern pitch between the turns constituting the intermediate turn 113.

### Third Embodiment

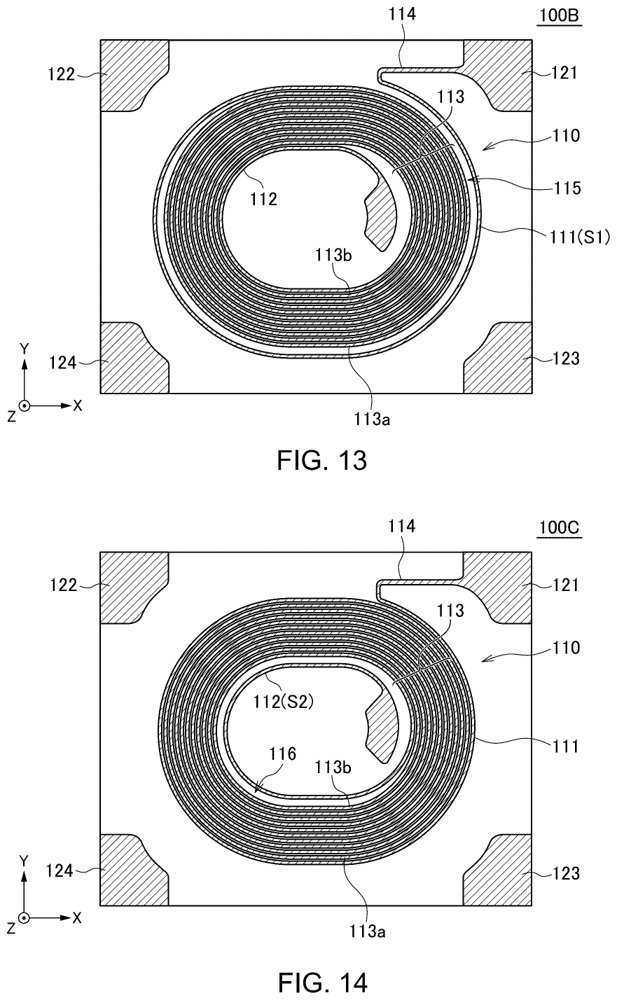

FIG. 13 is a schematic plan view for explaining the pattern shape of a conductor layer 100B used for a common mode filter according to a third embodiment of the technology described herein.

As illustrated in FIG. 13, the conductor layer 100B used for the common mode filter according to the third embodiment differs from the conductor layer 100 illustrated in FIG. 2 in that the innermost turn 112 of the coil pattern 110 does not include the non-overlap section S2. That is, the radial space between the turns of the coil pattern 110 excluding the outermost turn 111 is substantially constant. Other basic configurations are the same as those of the common mode filter 1 according to the first embodiment, so the same reference numerals are given to the same elements, and overlapping description will be omitted.

As exemplified in the third embodiment, a configuration may be employed in which the innermost turn 112 of the coil pattern 110 does not include the non-overlap section S2, while the outermost turn 111 of the coil pattern 110 includes the non-overlap section S1.

### Fourth Embodiment

FIG. 14 is a schematic plan view for explaining the pattern shape of a conductor layer 100C used for a common mode filter according to a fourth embodiment of the technology described herein.

As illustrated in FIG. 14, the conductor layer 100C used for the common mode filter according to the fourth embodiment differs from the conductor layer 100 illustrated in FIG. 2 in that the outermost turn 111 of the coil pattern 110 does not include the non-overlap section S1. That is, the radial space between the turns of the coil pattern 110 excluding the innermost turn 112 is substantially constant. Other basic configurations are the same as those of the common mode filter 1 according to the first embodiment, so the same reference numerals are given to the same elements, and overlapping description will be omitted.

As exemplified in the fourth embodiment, a configuration may be employed in which the outermost turn 111 of the coil pattern 110 does not include the non-overlap section S1, while the innermost turn 112 of the coil pattern 110 includes the non-overlap section S2.

### Fifth Embodiment

A common mode filter according to a fifth embodiment of the technology described herein has a structure in which four conductor layers 100B, 200, 300A, and 400 stacked through insulating layers are embedded in the element body 2. The conductor layer 100B has a pattern shape illustrated in FIG. 13, and the conductor layer 200 has a pattern shape illustrated in FIG. 4. The insulating layer 10 positioned between the conductor layers 100B and 200 has a shape illustrated in FIG. 3, and the insulating layer 20 positioned between the conductor layers 200 and 300A has a shape illustrated in FIG. 5.

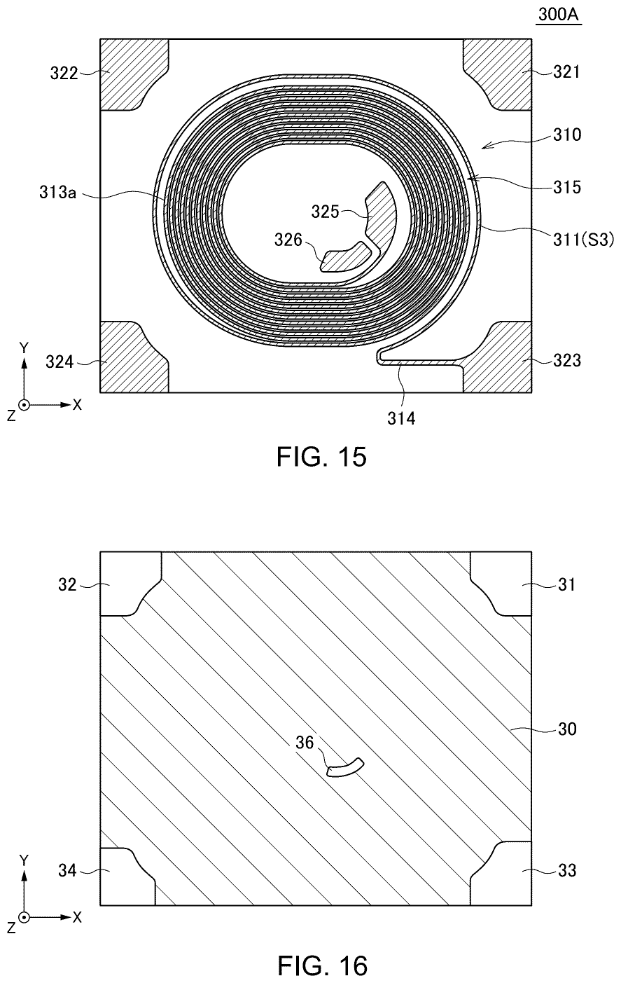

FIG. 15 is a schematic plan view for explaining the pattern shape of a conductor layer 300A used for the common mode filter according to the fifth embodiment.

As illustrated in FIG. 15, the conductor layer 300A used for the common mode filter according to the fifth embodiment has a coil pattern 310 and differs from the conductor layer 300 illustrated in FIG. 6 in that the connection pattern 323 is connected to the outer peripheral end of the coil pattern 310, the connection pattern 325 is connected to the inner peripheral end of the coil pattern 310, and the connection pattern 326 is independently provided without being connected to another conductor pattern in the conductor layer 300A. Other basic configurations are the same as those of the conductor layer 300 illustrated in FIG. 6, so the same reference numerals are given to the same elements, and overlapping description will be omitted.

In the example illustrated in FIG. 15, the coil pattern 310 has about 12 turns. The outer peripheral end of the coil pattern 310 is connected to the connection pattern 323 by way of a lead-out part 314. The coil pattern 310 is wound left-handed (counterclockwise) from the outer peripheral end to the inner peripheral end, whereas the lead-out part 314 linearly extends in the negative X-direction from the outer peripheral end to the inner peripheral end without being wound left-handed (counterclockwise). The connection patterns 321, 322, 324, and 326 are each independently provided without being connected to another conductor pattern in the conductor layer 300A.

FIG. 16 is a schematic plan view of the insulating layer 30 used for the common mode filter according to the fifth embodiment.

The insulating layer 30 differs from the insulating layer 30 illustrated in FIG. 7 in that it is positioned between the conductor layer 300A and the conductor layer 400 and has an opening 36. The opening 36 is formed at a position exposing the connection pattern 326. Other basic configurations are the same as those of the insulating layer 30 illustrated in FIG. 7, so the same reference numerals are given to the same elements, and overlapping description will be omitted.

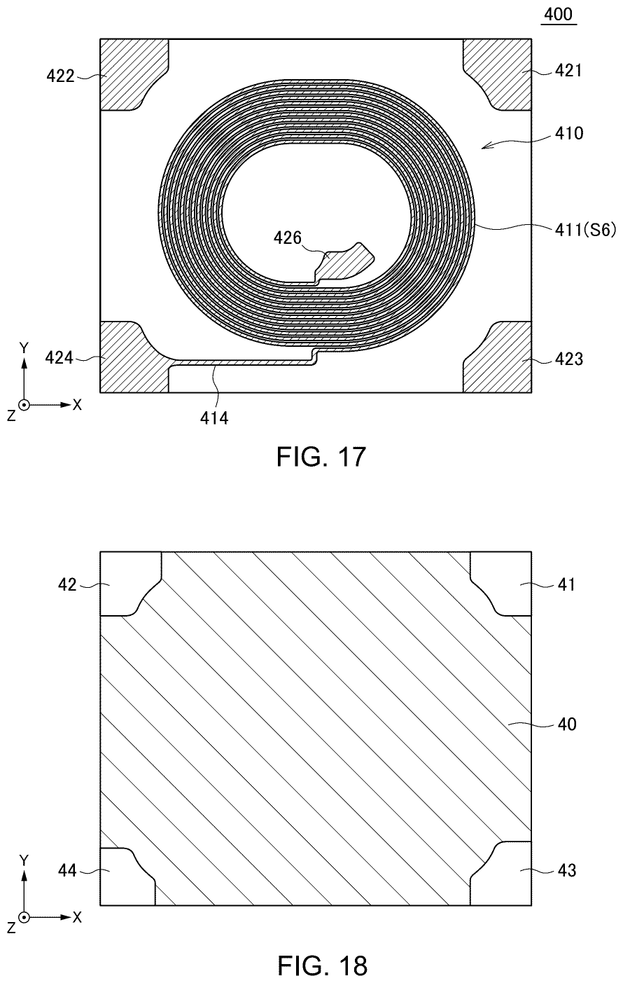

FIG. 17 is a schematic plan view for explaining the pattern shape of the conductor layer 400.

The conductor layer 400 has a spiral coil pattern 410 and connection patterns 421 to 424 and 426. In the example illustrated in FIG. 17, the coil pattern 410 has about 12 turns. That is, the number of turns of the coil pattern 310 and that of the coil pattern 410 are substantially the same. The outer peripheral end of the coil pattern 410 is connected to the connection pattern 424 by way of a lead-out part 414. The inner peripheral end of the coil pattern 410 is connected to the connection pattern 426. The coil pattern 410 is wound left-handed (counterclockwise) from the outer peripheral end to the inner peripheral end, whereas the lead-out part 414 linearly extends in the positive X-direction from the outer peripheral end to the inner peripheral end. The connection patterns 421 to 423 are each independently provided without being connected to another conductor pattern in the conductor layer 400. The connection patterns 421 to 424 and 426 are connected respectively to the connection patterns 321 to 324 and 326 through the respective openings 31 to 34 and 36 formed in the insulating layer 30.

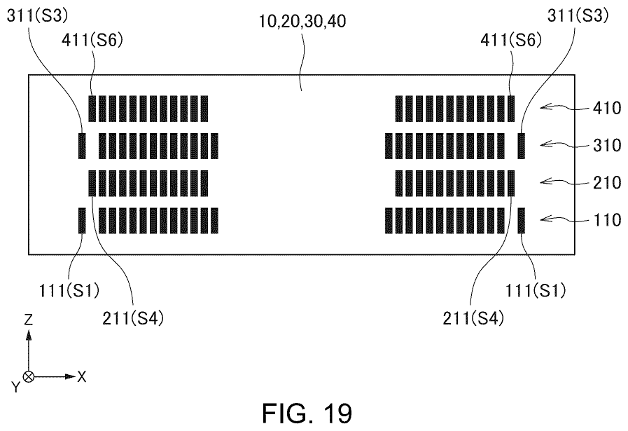

FIG. 18 is a schematic plan view of the insulating layer 40.

The insulating layer 40 is the uppermost insulating layer and has openings 41 to 44. The openings 41 to 44 are formed at positions respectively exposing therethrough the connection patterns 421 to 424. The terminal electrodes E1 to E4 illustrated in FIG. 1 are connected respectively to the connection patterns 421 to 424 through the respective openings 41 to 44.

With the above configuration, the outer peripheral end of the coil pattern 110 is connected to the terminal electrode E1, the outer peripheral end of the coil pattern 210 is connected to the terminal electrode E2, the outer peripheral end of the coil pattern 310 is connected to the terminal electrode E3, and the outer peripheral end of the coil pattern 410 is connected to the terminal electrode E4. Further, the inner peripheral end of the coil pattern 110 and the inner peripheral end of the coil pattern 310 are connected to each other, and the inner peripheral end of the coil pattern 210 and the inner peripheral end of the coil pattern 410 are connected to each other. As a result, the coil patterns 110 and 310 connected between the terminal electrodes E1 and E3 and the coil patterns 210 and 410 connected between the terminal electrodes E2 and E4 are coupled to each other.

As illustrated in FIG. 15, in the present embodiment, the radial space between adjacent turns of the coil pattern 310 is not constant, but a space 315 between the outermost turn 311 and a turn 313a which is the second turn counting from the outermost peripheral side are made larger than spaces each between other adjacent turns. The space 315 is larger than the pattern width of the coil pattern 410. The space 315 may be larger than the pattern width of the coil pattern 210. The radial space between the turns of the coil pattern 310 excluding the outermost turn 311 is substantially constant.

Thus, as illustrated in FIG. 19 which is a schematic cross-sectional view, the outermost turn 311 of the coil pattern 310 and the outermost turn 411 of the coil pattern 410 do not overlap each other at least partially. A part of the outermost turn 311 of the coil pattern 310 that do not overlap the outermost turn 411 of the coil pattern 410 constitutes a non-overlap section S3. The non-overlap section S3 may not overlap the outermost turn 211 of the coil pattern 210. A part of the outermost turn 411 of the coil pattern 410 that do not overlap the outermost turn 311 of the coil pattern 310 constitutes a non-overlap section S6.

As described above, since the outermost turns 111, 211, 311, and 411 of the coil patterns 110, 210, 310, and 410 respectively have the non-overlap sections S1, S4, S3, and S6, inter-wire capacitance occurring between the outermost turns 111 and 211 and inter-wire capacitance occurring between the outermost turns 311 and 411 are reduced. As a result, the capacitance component C1 around the terminal electrodes E1 and E2 is reduced, and the capacitance component C2 around the terminal electrodes E3 and E4 is reduced. Further, when the non-overlap section S3 does not overlap the outermost turn 211 of the coil pattern 210, inter-wire capacitance between the outermost turns 211 and 311 is also reduced.

On the other hand, the turns other than the outermost turns 111, 211, 311, and 411 of the coil patterns 110, 210, 310, and 410 overlap one another. This enhances coupling between the coil patterns 110 and 310 and between the coil patterns 210 and 410.

As exemplified in the fifth embodiment, the following configuration may be employed: the four coil patterns 110, 210, 310, and 410 are stacked one on another in this order, the inner peripheral ends of the coil patterns 110 and 310 are connected to each other, and the inner peripheral ends of the coil patterns 210 and 410 are connected to each other. Thus, the terminal electrodes E1 to E4 are connected respectively to the outermost turns 111, 211, 311, and 411 of the coil patterns 110, 210, 310, and 410, which reduces a difference in characteristics between when the terminal electrodes E1 and E2 are set as the input side and the terminal electrodes E3 and E4 are set as the output side and when the terminal electrodes E1 and E2 are set as the output side and the terminal electrodes E3 and E4 are set as the input side.

While some embodiments of the technology according to the present disclosure have been described, the technology according to the present disclosure is not limited to the above embodiments, and various modifications may be made within the scope of the present disclosure, and all such modifications are included in the technology according to the present disclosure.

The technology according to the present disclosure includes the following configuration examples, but not limited thereto.

A common mode filter according to an aspect of the present disclosure includes: a plurality of conductor layers stacked with an insulating layer interposed therebetween, the plurality of conductor layers including at least first and second conductor layers; and first, second, third, and fourth terminal electrodes. The first conductor layer has a spiral-shaped first coil pattern having an outer peripheral end connected to the first terminal electrode and an inner peripheral end connected to the third terminal electrode. The second conductor layer has a spiral-shaped second coil pattern having an outer peripheral end connected to the second terminal electrode and an inner peripheral end connected to the fourth terminal electrode. The outermost turn of the first coil pattern has a first non-overlap section that is wound at least by ¼ turn without overlapping the outermost turn of the second coil pattern, or the innermost turn of the first coil pattern has a second non-overlap section that is wound at least by ¼ turn without overlapping the innermost turn of the second coil pattern. With this configuration, it is possible to reduce inter-wire capacitance around the first and second terminal electrodes or inter-wire capacitance around the third and fourth terminal electrodes.

In the above common mode filter, the first coil pattern may have both the first and second non-overlap sections. This makes it possible to reduce both the inter-wire capacitance around the first and second terminal electrodes and the inter-wire capacitance around the third and fourth terminal electrodes.

In the above common mode filter, the plurality of conductor layers may further include third and fourth conductor layers, the first, second, third, and fourth conductor layers may be stacked in this order through the insulating layers, the third conductor layer may have a spiral-shaped third coil pattern having an outer peripheral end connected to the third terminal electrode and an inner peripheral end connected to the inner peripheral end of the first coil pattern, the fourth conductor layer may have a spiral-shaped fourth coil pattern having an outer peripheral end connected to the fourth terminal electrode and an inner peripheral end connected to the inner peripheral end of the second coil pattern, the outermost turn of the first coil pattern may have the non-overlap section, and the outermost turn of the third coil pattern may have a third non-overlap section that is wound at least by ¼ turn without overlapping the outermost turn of the fourth coil pattern. This reduces a difference in characteristics between when the first and second terminal electrodes are set as the input side and the third and fourth terminal electrodes are set as the output side and when the first and second terminal electrodes are set as the output side and the third and fourth terminal electrodes are set as the input side.

In the above common mode filter, a first space in a radial direction between the first non-overlap section of the first coil pattern and a second outermost turn of the first coil pattern, or a second space in the radial direction between the second non-overlap section of the first coil pattern and a second innermost turn of the first coil pattern may be larger than a space in the radial direction between turns constituting an intermediate turn positioned between the second outermost turn and the second innermost turn. This can reduce the radial size of the first coil pattern.

In the above common mode filter, at least one of the first and second spaces may be larger than the pattern width of the second coil pattern. This allows the second coil pattern to be disposed at a position overlapping at least one of the first and second spaces.

In the above common mode filter, the pattern pitch between the first non-overlap section and the intermediate turn, or the pattern pitch between the second non-overlap section and the intermediate turn may be set to twice or more of the pattern pitch between the turns constituting the intermediate turn. This allows a dummy pattern to be disposed in at least one of the first and second spaces.

In the above common mode filter, the first conductor layer may further have a first dummy pattern disposed in the first space or a second dummy pattern disposed in the second space. This facilitates formation of the second coil pattern.

In the above common mode filter, the pattern width of the first or second non-overlap section may be smaller than the pattern width of the turns constituting the intermediate turn. This can further reduce the inter-wire capacitance around the first and second terminal electrodes or the inter-wire capacitance around the third and fourth terminal electrodes.

In the above common mode filter, the turns constituting the intermediate turns may all overlap the second coil pattern. This enhances coupling between the first and second coil patterns.

What is claimed is:

1. A common mode filter comprising:
a plurality of conductor layers stacked with an insulating layer interposed therebetween, the plurality of conductor layers including at least first and second conductor layers; and
first, second, third, and fourth terminal electrodes,
wherein the first conductor layer has a spiral-shaped first coil pattern having an outer peripheral end connected to the first terminal electrode and an inner peripheral end connected to the third terminal electrode,
wherein the second conductor layer has a spiral-shaped second coil pattern having an outer peripheral end connected to the second terminal electrode and an inner peripheral end connected to the fourth terminal electrode, and
wherein an outermost turn of the first coil pattern has a first non-overlap section that is wound at least by ¼ turn without overlapping an outermost turn of the second coil pattern.

2. The common mode filter as claimed in claim 1, wherein an innermost turn of the first coil pattern has a second non-overlap section that is wound at least by ¼ turn without overlapping an innermost turn of the second coil pattern.

3. The common mode filter as claimed in claim 1,
wherein the plurality of conductor layers further include third and fourth conductor layers,
wherein the first, second, third, and fourth conductor layers are stacked in this order through the insulating layers,
wherein the third conductor layer has a spiral-shaped third coil pattern having an outer peripheral end connected to the third terminal electrode and an inner peripheral end connected to the inner peripheral end of the first coil pattern,
wherein the fourth conductor layer has a spiral-shaped fourth coil pattern having an outer peripheral end connected to the fourth terminal electrode and an inner peripheral end connected to the inner peripheral end of the second coil pattern, and
wherein an outermost turn of the third coil pattern has a third non-overlap section that is wound at least by ¼ turn without overlapping an outermost turn of the fourth coil pattern.

4. The common mode filter as claimed in claim 1, wherein a first space in a radial direction between the first non-overlap section of the first coil pattern and a second outermost turn of the first coil pattern is larger than a space in the radial direction between adjacent turns constituting intermediate turns positioned between the second outermost turn and a second innermost turn.

5. The common mode filter as claimed in claim 4, wherein the first space is larger than a pattern width of the second coil pattern.

6. The common mode filter as claimed in claim 5, wherein a pattern pitch between the first non-overlap section and the second outermost turn is set to twice or more of a pattern pitch of the intermediate turns.

7. The common mode filter as claimed in claim 6, wherein the first conductor layer further has a first dummy pattern disposed in the first space.

8. The common mode filter as claimed in claim 4, wherein a pattern width of the first non-overlap section is smaller than a pattern width of each of the intermediate turns.

9. The common mode filter as claimed in claim 4, wherein each of the intermediate turns overlaps the second coil pattern.

10. A common mode filter comprising:
a plurality of conductor layers stacked with an insulating layer interposed therebetween, the plurality of conductor layers including at least first and second conductor layers; and
first, second, third, and fourth terminal electrodes,
wherein the first conductor layer has a spiral-shaped first coil pattern having an outer peripheral end connected to the first terminal electrode and an inner peripheral end connected to the third terminal electrode,
wherein the second conductor layer has a spiral-shaped second coil pattern having an outer peripheral end connected to the second terminal electrode and an inner peripheral end connected to the fourth terminal electrode, and
wherein an innermost turn of the first coil pattern has a first non-overlap section that is wound at least by ¼ turn without overlapping an innermost turn of the second coil pattern.

11. The common mode filter as claimed in claim 10,
wherein the plurality of conductor layers further include third and fourth conductor layers,
wherein the first, second, third, and fourth conductor layers are stacked in this order through the insulating layers,
wherein the third conductor layer has a spiral-shaped third coil pattern having an outer peripheral end connected to the third terminal electrode and an inner peripheral end connected to the inner peripheral end of the first coil pattern,
wherein the fourth conductor layer has a spiral-shaped fourth coil pattern having an outer peripheral end connected to the fourth terminal electrode and an inner peripheral end connected to the inner peripheral end of the second coil pattern, and
wherein an innermost turn of the third coil pattern has a second non-overlap section that is wound at least by ¼ turn without overlapping an innermost turn of the fourth coil pattern.

12. The common mode filter as claimed in claim 10, wherein a first space in a radial direction between the first non-overlap section of the first coil pattern and a second innermost turn of the first coil pattern is larger than a space in the radial direction between adjacent turns constituting intermediate turns positioned between the second innermost turn and a second outermost turn.

13. The common mode filter as claimed in claim 12, wherein the first space is larger than a pattern width of the second coil pattern.

14. The common mode filter as claimed in claim 13, wherein a pattern pitch between the first non-overlap section and the second innermost turn is set to twice or more of a pattern pitch of the intermediate turns.

15. The common mode filter as claimed in claim 14, wherein the first conductor layer further has a first dummy pattern disposed in the first space.

16. The common mode filter as claimed in claim 12, wherein a pattern width of the first non-overlap section is smaller than a pattern width of each of the intermediate turns.

17. The common mode filter as claimed in claim 12, wherein each of the intermediate turns overlaps the second coil pattern.
